(19) United States
(12) Patent Application Publication
(10) Pub. No.: US 2025/0120117 A1
(43) Pub. Date: Apr. 10, 2025

(54) FIELD EFFECT TRANSISTOR HAVING A TRENCH GATE STRUCTURE

(71) Applicant: Infineon Technologies Dresden GmbH & Co. KG, Dresden (DE)

(72) Inventors: Andreas Meiser, Sauerlach (DE); Andreas Hoffmann, München (DE); Ralf Rudolf, Dresden (DE); Christian Kampen, München (DE); Jonas Mertens, München (DE)

(21) Appl. No.: 18/910,508

(22) Filed: Oct. 9, 2024

(30) Foreign Application Priority Data
Oct. 10, 2023 (DE) 102023209915.2

(51) Int. Cl. H01L 29/78; H01L 29/06; H01L 29/423; H01L 29/66

(52) U.S. Cl. CPC H10D 30/658; H10D 30/0289; H10D 62/125; H10D 64/513

(57) ABSTRACT

A FET includes a transistor cell which includes: a source region at a first surface of a semiconductor substrate; a drain region spaced along a first lateral direction from the source region; a trench gate structure arranged, along the first lateral direction, between the source and drain regions; a body region adjoining the trench gate structure; and a body contact region. At least one of the following conditions is satisfied: a first vertical distance from the body contact region bottom side to a vertical reference level at the first surface is larger than a second vertical distance from the source region bottom side to the vertical reference level; and a first lateral distance from an edge of the body contact region to a lateral reference level at the drain region is smaller than a second lateral distance from an edge of the source region to the lateral reference level.

### TECHNICAL FIELD

The present disclosure is related to a semiconductor device, in particular to a field effect transistor, FET, comprising a trench gate structure.

### BACKGROUND

Technology development of new generations of semiconductor devices, e.g. field effect transistors (FETs), aims at improving electric device characteristics and reducing costs by shrinking device geometries. Although costs may be reduced by shrinking device geometries, a variety of tradeoffs and challenges has to be met when increasing device functionalities per unit area. For example, a trade-off between area-specific on-state resistance, RₒₙxA and reliability requirements influenced by, for example, avalanche breakdown behavior requires design optimization.

Thus, there is a need for an improved field effect transistor.

### SUMMARY

An example of the present disclosure relates to a field effect transistor, FET. The FET includes a transistor cell in a semiconductor substrate having a first surface. The transistor cell comprises a source region including dopants of a first conductivity type at a first surface of the semiconductor substrate. The transistor cell further comprises a drain region including dopants of the first conductivity type. The drain region is spaced along a first lateral direction from the source region. The transistor cell further comprises a trench gate structure arranged, along the first lateral direction, between the source region and the drain region. The transistor cell further comprises a body region of a second conductivity type that adjoins to the trench gate structure. The transistor cell further comprises a body contact region including dopants of the second conductivity type. An arrangement of the source region and the body contact region satisfies at least one of the following conditions: i) a first vertical distance from a bottom side of the body contact region to a vertical reference level at the first surface is larger than a second vertical distance from a bottom side of the source region to the vertical reference level, or ii) a first lateral distance, along the first lateral direction, from a first edge of the body contact region to a lateral reference level at the drain region is smaller than a second lateral distance, along the first lateral direction, from a first edge the source region to the lateral reference level.

Another example of the present disclosure relates to a method of manufacturing a field effect transistor, FET, comprising a transistor cell in a semiconductor substrate having a first surface. Forming the transistor cell includes forming a source region including dopants of a first conductivity type at a first surface of the semiconductor substrate. Forming the transistor cell further includes forming a drain region including dopants of the first conductivity type. The drain region is spaced along a first lateral direction from the source region. Forming the transistor cell further includes forming a trench gate structure arranged, along the first lateral direction, between the source region and the drain region. Forming the transistor cell further includes forming a body region of a second conductivity type that adjoins to the trench gate structure. Forming the transistor cell further includes forming a body contact region including dopants of the second conductivity type. An arrangement of the source region and the body contact region satisfies at least one of the following conditions: i) a first vertical distance from a bottom side of the body contact region to a vertical reference level at the first surface is larger than a second vertical distance from a bottom side of the source region to the vertical reference level, or ii) a first lateral distance, along the first lateral direction, from a first edge of the body contact region to a lateral reference level at the drain region is smaller than a second lateral distance, along the first lateral direction, from a first edge of the source region to the lateral reference level.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of semiconductor devices and together with the description serve to explain principles of the examples. Further examples are described in the following detailed description and the claims.

FIGS. 1A to 1D are schematic top and cross-sectional views for illustrating a configuration example of a FET including a trench gate structure.

FIGS. 2 and 3 are schematic top and cross-sectional views for illustrating further configuration examples of a FET including a trench gate structure.

FIGS. 4A and 4B are schematic top and cross-sectional views for illustrating a configuration example of a FET that is based on FIGS. 1A to 1D and further includes a trench field plate structure.

FIGS. 5A and 5B are schematic top and cross-sectional views for illustrating a further configuration example of a FET including a trench gate structure.

FIGS. 6A and 6B are schematic cross-sectional views for illustrating further configuration examples of a FET including a trench gate structure.

### DETAILED DESCRIPTION

In the following detailed description, reference is made to the accompanying drawings, which form a part hereof and in which are shown by way of illustrations specific examples of FETs. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions may include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a field effect transistor, FET. The FET includes a transistor cell in a semiconductor substrate having a first surface. The transistor cell comprises a source region including dopants of a first conductivity type at a first surface of the semiconductor substrate. The transistor cell further comprises a drain region including dopants of the first conductivity type. The drain region is spaced along a first lateral direction from the source region. The transistor cell further comprises a trench gate structure arranged, along the first lateral direction, between the source region and the drain region. The transistor cell further comprises a body region of a second conductivity type that adjoins to the trench gate structure. The transistor cell further comprises a body contact region including dopants of the second conductivity type. An arrangement of the source region and the body contact region may satisfy at least one of the following conditions: i) a first vertical distance from a bottom side of the body contact region to a vertical reference level at the first surface is larger than a second vertical distance from a bottom side of the source region to the vertical reference level, or ii) a first lateral distance, along the first lateral direction, from a first edge of the body contact region to a lateral reference level at the drain region is smaller than a second lateral distance, along the first lateral direction, from a first edge the source region to the lateral reference level. For example, for condition i), the body contact region may adjoin the body region at the bottom side of the body contact region. For example, for condition ii), the first lateral distance may refer to the first surface.

The first conductivity type may be an n-type and the second conductivity type may be a p-type. In this case, the FET may be an n-channel FET, for example. The first conductivity type may also be a p-type and the second conductivity type may be an n-type. In this case, the FET may be a p-channel FET, for example.

For example, the FET may be a lateral FET. In a lateral FET, a load current flow direction is a lateral direction, e.g. the first lateral direction, and the source region and the drain region are spaced from each other along the first lateral direction. For example, the lateral FET may be a lateral trench FET such as a lateral trench metal oxide semiconductor field effect transistor, lateral trench MOSFET. In the trench gate structure, a trench gate dielectric may line sidewalls and a bottom side of a trench and may electrically isolate a trench gate electrode from a surrounding part of the semiconductor substrate. In the lateral trench FET, a channel current may flow along the first lateral direction at opposite sidewalls and along a bottom side of the trench gate structure, for example.

For example, the FET may be implemented monolithically using a mixed technology. Such mixed technologies can be used, for example, to form analog circuit blocks in a chip by the bipolar devices included in this technology for providing interfaces to digital systems, and to form digital circuit blocks by the complementary metal-oxide-semiconductor (CMOS) devices included in this technology for providing signal processing, and to form low-, medium- or high-voltage or power blocks by field effect transistors included in this technology. Such mixed technologies are known, for example, as bipolar CMOS-DMOS, BCD technologies or smart power technologies, SPT, and are used in a variety of application areas in the field of e.g. lighting, motor control, automotive electronics, power management for mobile devices, audio amplifiers, power supply, hard disks, printers. The FET may be part of a BCD or Smart Power chip in one of the above application fields, for example.

The semiconductor substrate may be based on various semiconductor materials, for example silicon (Si), silicon-on-insulator (SOI), silicon-sapphire (SOS), silicon-germanium, germanium, gallium arsenide, silicon carbide, gallium nitride, or other compound semiconductor materials. The semiconductor substrate may be based on a semiconductor base substrate, for example a semiconductor wafer and may include one or more epitaxial layers deposited thereon and/or may be back-thinned.

For realizing a desired current carrying capacity, the FET may be designed by a plurality of transistor cells that are parallel-connected. The parallel-connected transistor cells may, for example, be transistor cells formed in the shape of a strip or a strip segment. Of course, the transistor cells can also have any other shape, e.g. circular, elliptical, polygonal such as hexagonal or octahedral. The transistor cells may be arranged in a transistor cell area of the semiconductor substrate. The transistor cell area may be an active area where the source region of the FET and the drain region of the FET are arranged opposite to one another along the first lateral direction. In the active area, a load current may enter or exit the semiconductor substrate of the FET, e.g. via contact plugs on the first surface of the semiconductor substrate.

The first surface may be a front surface or a top surface of the semiconductor substrate, and the second surface may be a back surface or a rear surface of the semiconductor substrate, for example. The semiconductor substrate may be attached to a lead frame via the second surface, for example. Over the first surface of the semiconductor substrate, bond pads may be arranged and bond wires may be bonded on the bond pads, for example.

The source region and the body contact region may be electrically connected to a source electrode. The source electrode may be part of a wiring area over the first surface of the semiconductor substrate, for example. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. The source electrode may be formed by one or more elements of the wiring area. Likewise, the FET may further include a drain electrode. Also the drain electrode may be formed by one or more elements of the wiring area over the first surface. For example, the source electrode and the drain electrode may include separate parts of a patterned first wiring level, e.g. a first metal layer. In some examples, the drain electrode may also be formed over the second surface of the semiconductor substrate. In this case, a drain region of the FET may be electrically connected to the drain electrode by a through contact or trench contact extending at least partly through the semiconductor substrate.

The trench gate structure may include a trench gate dielectric and a trench gate electrode. The trench gate dielectric electrically isolates the trench gate electrode from a surrounding part of the semiconductor substrate, for example. For example, the trench gate dielectric may be an insulating material such as an oxide, e.g., SiO₂, a nitride, e.g., Si₃N₄, a high-k dielectric, or a low-k dielectric, or any combination thereof. For example, the trench gate dielectric may be formed as a thermal oxide. The trench gate electrode may be formed of one or more conductive materials, e.g. metal, metal silicide, metal compound, highly doped semiconductor material such as highly doped polycrystalline silicon. For example, the trench gate electrode may be a single layer, e.g. a highly doped polycrystalline layer, or a stack of layers. For example, the source region may adjoin to a first sidewall of the trench gate structure. A drift region of the first conductivity type may be arranged, along the first lateral direction, between the trench gate structure and the drain region. The drift region may adjoin to a second sidewall of the trench gate structure. The second sidewall may be opposite to the first sidewall along the first lateral direction.

The first vertical distance from the bottom side of the body contact region to the vertical reference level may be measured with respect to a lowermost position of the body contact region, e.g. a position of the body contact region that is located furthest to the first surface and closest to the second surface. Likewise, the second vertical distance from the bottom side of the source region to the vertical reference level may be measured with respect to a lowermost position of the source region, e.g. a position of the source region that is located furthest to the first surface and closest to the second surface. The vertical reference level may be any vertical reference level close to or coinciding with the first surface.

The first lateral distance, along the first lateral direction, from the first edge of the body contact region to the lateral reference level at the drain region may refer to a position of the first edge, e.g. with respect to vertical and horizontal location, that is closest to the lateral reference level along the first lateral direction. Likewise, the second lateral distance, along the first lateral direction, from the first edge of the source region to the lateral reference level at the drain region may refer to a position of the first edge, e.g. with respect to vertical and horizontal location, that is closest to the lateral reference level along the first lateral direction. The lateral reference level may be any lateral reference level close to or coinciding with an edge of the drain region.

By arranging the body contact region and the source region as defined in the conditions i) and/or ii) above, in case of an n-channel FET, holes generated by electric breakdown at a pn junction between the body region and a drift region may be discharged at a larger distance to the source region. Thereby, a voltage drop between of the body contact region and the source region may be reduced. This may allow for suppressing triggering of a parasitic bipolar transistor or may allow for increasing a trigger current of the parasitic bipolar transistor having the source region as the emitter and the body contact region as the base. This may allow for improving reliability of the FET without adversely affecting the RₒₙxA.

For example, the first vertical distance may be larger by 50 nm to 1000 nm, or by 100 nm to 500 nm, than the second vertical distance. This may allow for suppressing triggering of the parasitic bipolar transistor or may allow for increasing a trigger current of the parasitic bipolar transistor.

For example, the first lateral distance may be smaller by 50 nm to 500 nm, or by 75 nm to 400 nm, than the second lateral distance. This may allow for suppressing triggering of the parasitic bipolar transistor or may allow for increasing a trigger current of the parasitic bipolar transistor.

For example, the dopants of the second conductivity type of the body contact region may line at least part of a sidewall of a body contact trench extending into the semiconductor substrate from the first surface. In some examples, the dopants of the second conductivity type may further line a bottom side of the body contact trench. For example, the dopants of the second conductivity type may be introduced into the body contact region via sidewalls and/or a bottom side of the body contact trench, e.g. by diffusion out of a dopant source such as a solid state dopant source and/or by ion implantation. For example, the body contact region may include further conductive material(s), e.g. metal(s) and/or doped semiconductor material(s).

For example, the first vertical distance may be larger than a third vertical distance from a bottom side of the trench gate structure to the vertical reference level.

For example, the dopants of the first conductivity type of the source region may line at least part of a sidewall of a source contact trench extending into the semiconductor substrate from the first surface. In some examples, the dopants of the first conductivity type may further line a bottom side of the source contact trench. For example, the dopants of the first conductivity type may be introduced into the source region via sidewalls and/or a bottom side of the source contact trench, e.g. by diffusion out of a dopant source such as a solid state dopant source and/or by ion implantation. For example, the source region may include further conductive material(s), e.g. metal(s) and/or doped semiconductor material(s). For example, a depth of the source contact trench may be equal to, or smaller, or larger than a depth of the body contact trench. For example, a depth of the body contact trench may be larger than a depth of the source contact trench. According to a further example, a depth of the body contact trench may be equal to a depth of the source contact trench, and a vertical extension of dopants of the second conductivity type of the body contact region from a bottom side of the body contact trench to a bottom side of the body contact region may be larger than a vertical extension of dopants of the first conductivity type of the source region from a bottom side of the source contact trench to a bottom side of the source region.

For example, the body contact region may include a buried body contact sub-region. The buried body contact sub-regions of neighboring body contact regions may overlap or adjoin one another along a second lateral direction. In some examples, a buried contact sub-region may also be formed below the source region and may adjoin the bottom side of the source region.

For example, the second vertical distance may be larger than a third vertical distance from a bottom side of the trench gate structure to the vertical reference level.

For example, the body region may adjoin to a bottom side of the trench gate structure. For example, the body region may adjoin to the bottom side of the trench gate structure and to opposite sidewalls of the trench gate structure. Thereby, a channel region may be formed at the opposite sidewalls and at the bottom side of the trench gate structure. Along the first lateral direction, the body region may adjoin to more than 60%, or more than 70%, or more than 80%, or more than 90% of a lateral extent of the bottom side along the first lateral direction.

For example, the source region may adjoin to the body contact region along a second lateral direction. The second lateral direction may be perpendicular to the first lateral direction. In a transistor cell array including a plurality of the transistor cells, the source and body contact regions may be alternately arranged along the second lateral direction, for example.

For example, the dopants of the first conductivity type of the drain region may line at least part of a sidewall of a drain contact trench extending into the semiconductor substrate from the first surface. In some examples, the dopants of the first conductivity type may further line a bottom side of the drain contact trench. For example, the dopants of the first conductivity type may be introduced into the drain region via sidewalls and/or a bottom side of the drain contact trench, e.g. by diffusion out of a dopant source such as a solid state dopant source and/or by ion implantation. For example, the drain region may include further conductive material(s), e.g. metal(s) and/or doped semiconductor material(s).

For example, a fourth vertical distance from a bottom side of the drain region to the vertical reference level may be larger than the second vertical distance.

For example, the FET may further include a trench field plate structure arranged, along the first lateral direction, between the trench gate structure and the drain region. The trench gate structure may be spaced from the trench field plate structure along the first lateral direction. For example, a width (e.g. extent along the second lateral direction) of the trench field plate structure may be larger, e.g. by more than 20% and by less than 100%, than a width of the trench gate structure. For example, in a transistor cell area, a pitch of arrangement of the trench field plate structures along the second lateral direction may be equal to a pitch of arrangement of the trench gate structures along the second lateral direction. The trench field plate structures and the trench gate structures may be offset from each other along the second lateral direction, e.g. offset by half of the pitch.

Similar to the trench gate structure, the trench field plate structure may include a trench field plate dielectric and a trench field plate electrode. The trench field plate dielectric electrically isolates the trench field plate electrode from a surrounding part of the semiconductor substrate, for example. The trench field plate dielectric may have a larger thickness than the trench gate dielectric, for example. For example, the trench field plate dielectric may be an insulating material such as an oxide, e.g., SiO₂, a nitride, e.g., Si₃N₄, a high-k dielectric, or a low-k dielectric, or any combination thereof. For example, the trench field plate dielectric may be formed as or include a thermal oxide and/or a deposited and annealed oxide. The trench field plate electrode may be formed of one or more conductive materials, e.g. metal, metal silicide, metal compound, highly doped semiconductor material such as highly doped polycrystalline silicon. For example, the trench field plate electrode may be a single layer, e.g. a highly doped polycrystalline layer, or a stack of layers. For example, the trench gate electrode and the trench field plate electrode may be made of the same material or combination of materials, for example. Provision of the trench field plate structure may allow for a further reduction of the RₒₙxA.

For example, the FET may further include a fifth vertical distance from a bottom side of the body region to the vertical reference level. A difference of the fifth vertical distance and the first vertical distance may be larger than a difference of the first vertical distance and the second vertical distance.

For example, the semiconductor substrate may include a base substrate of the first conductivity type and a semiconductor layer of the first conductivity type. The semiconductor layer may be arranged on the base substrate and may have a smaller concentration of dopants of the first conductivity type than the base substrate. A drift region of the FET may be part of the semiconductor layer, for example.

For example, the body region may be a well region in the semiconductor layer. A pn junction between the body region and the semiconductor layer may include a side area and a bottom area. A drift region as part of the semiconductor layer may be arranged between the side area and the drain region. A sub-region of the semiconductor layer may be arranged between the bottom area and the base substrate.

For example, the body region, the body contact region and the semiconductor substrate may be configured to provide an electric breakdown location of the pn junction at or close to the bottom area. The electric breakdown location may be located at a position where the area of the pn-junction has a smallest radius of curvature, for example.

For example, the electric breakdown location of the pn junction at the bottom area may be directly below a bottom side of the body contact region.

Details with respect to structure, or function, or technical benefit of features described above with respect to a semiconductor device such as a FET likewise apply to the exemplary methods described herein. Processing the semiconductor substrate may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded. Processing a semiconductor substrate wafer for manufacturing the FET may comprise one or more optional additional features corresponding to one or more aspects mentioned in connection with the proposed concept or one or more examples described above or below.

An example of the present disclosure relates to a method of manufacturing a field effect transistor, FET, comprising a transistor cell in a semiconductor substrate having a first surface. Forming the transistor cell may include forming a source region including dopants of a first conductivity type at a first surface of the semiconductor substrate. Forming the transistor cell may further include forming a drain region including dopants of the first conductivity type. The drain region may be spaced along a first lateral direction from the source region. Forming the transistor cell may further include forming a trench gate structure arranged, along the first lateral direction, between the source region and the drain region. Forming the transistor cell may further include forming a body region of a second conductivity type that adjoins to the trench gate structure. Forming the transistor cell may further include forming a body contact region including dopants of the second conductivity type. An arrangement of the source region and the body contact region may satisfy at least one of the following conditions: i) a first vertical distance from a bottom side of the body contact region to a vertical reference level at the first surface is larger than a second vertical distance from a bottom side of the source region to the vertical reference level, or ii) a first lateral distance, along the first lateral direction, from a first edge of the body contact region to a lateral reference level at the drain region is smaller than a second lateral distance, along the first lateral direction, from a first edge of the source region to the lateral reference level.

The examples and features described above and below may be combined.

In the following, further examples of field effect transistors, FETs, are explained in connection with the accompanying drawings. Functional and structural details described with respect to the examples above shall likewise apply to the exemplary embodiments illustrated in the figures and described further below. In the illustrated examples, the first conductivity is n-type and the second conductivity type is p-type for an n-channel FET. However, the first conductivity type may also be p-type and the second conductivity type may be n-type for a p-channel FET.

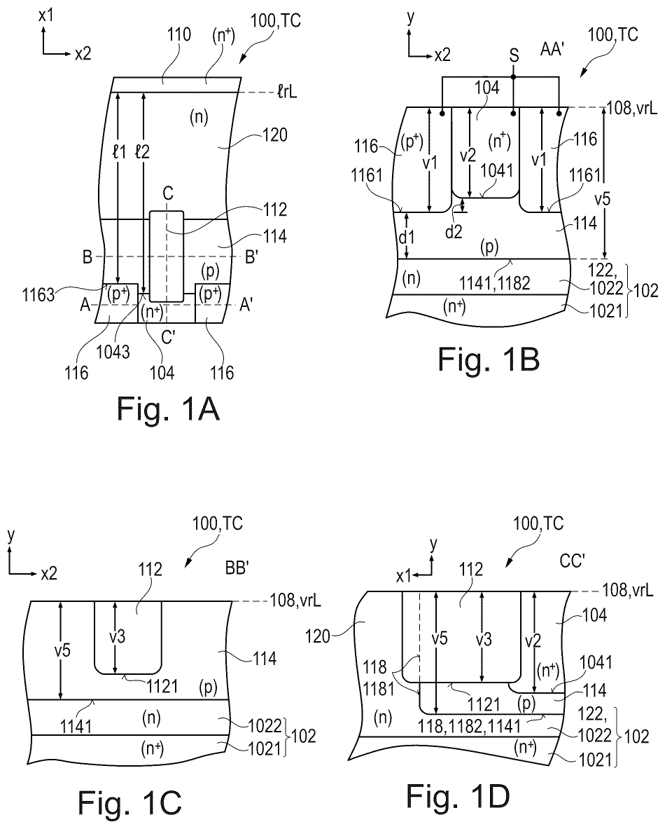

FIG. 1A schematically and exemplarily shows a top view of a part of a transistor cell TC of a FET 100. FIG. 1B schematically and exemplarily shows a cross-sectional view along line AA′ of FIG. 1A. FIG. 1C schematically and exemplarily shows a cross-sectional view along line BB′ of FIG. 1A. FIG. 1D schematically and exemplarily shows a cross-sectional view along line CC′ of FIG. 1A.

Referring to FIGS. 1A to 1D, the FET 100 includes the transistor cell TC in a semiconductor substrate 102. The semiconductor substrate 102 includes an n+-doped base substrate 1021 and an n-doped semiconductor layer 1022, e.g. an epitaxial layer formed by a layer deposition process. The semiconductor layer 1022 is arranged on the base substrate 1021 and has a smaller concentration of n-type dopants type than the base substrate 1021.

An n+-doped source region 104 is formed at the first surface 108 of the semiconductor substrate 102 and adjoins to a trench gate structure 112 along a first lateral direction x1. The n+-doped source region 104 is electrically connected to a source electrode S over the first surface 108 of the semiconductor substrate 102.

An n+-doped drain region 110 is spaced along the first lateral direction x1 from the source region 104 and from the trench gate structure 112.

A p-doped body region 114 adjoins to the trench gate structure 112. The p-doped body region 114 adjoins to opposite sidewalls of the trench gate structure 112 and to a bottom side 1121 of the trench gate structure 112. The p-doped body region 114 may be formed as a p-well in the semiconductor layer 1022. A pn junction 118 is located between the body region 114 and the semiconductor layer 1022 and includes a side area 1181 and a bottom area 1182. An n-doped drift region 120 is a part of the semiconductor layer 1022 that is arranged between the side area 1181 and the drain region 110. A sub-region 122 of the semiconductor layer 1022 is arranged between the bottom area 1182 of the body region 108 and the base substrate 1021.

The p-doped body region 114 is electrically connected to the source electrode S via a p+-doped body contact region 116. The n+-doped source region 104 adjoins to the p+-doped body contact region 116 along a second lateral direction x2 that is perpendicular to the first lateral direction x1. For example, p-type dopants of the body contact region 116 may line at least part of a sidewall of a body contact trench extending into the semiconductor substrate 102 from the first surface 108. Likewise, n-type dopants of the source region 104 may line at least part of a sidewall of a source contact trench extending into the semiconductor substrate 102 from the first surface 108. For example, the dimensions of the body contact trench may be smaller than the dimensions of the body contact region 116 in case the dopants of the body contact region are introduced through sidewalls and/or a bottom side of the body contact trench by ion implantation and/or diffusion. Likewise, the dimensions of the source contact trench may be smaller than the dimensions of the source region 104 in case the dopants of the source region are introduced through sidewalls and/or a bottom side of the source contact trench by ion implantation and/or diffusion.

As is illustrated in FIG. 1A, a first lateral distance I1, along the first lateral direction x1, from a first edge 1163 of the body contact region 116 to a lateral reference level IrL at the drain region 110 is smaller than a second lateral distance I2, along the first lateral direction x1, from a first edge 1043 of the source region 104 to the lateral reference level IrL. In some examples, the first lateral distance I1 is smaller by 50 nm to 500 nm than the second lateral distance I2.

As is illustrated in FIG. 1B, a first vertical distance v1, along a vertical direction y, from a bottom side 1161 of the body contact region 116 to a vertical reference level vrL at the first surface 108 of the semiconductor substrate 102 is larger than a second vertical distance v2 from a bottom side 1041 of the source region 104 to the vertical reference level vrL. In some examples, the first vertical distance v1 is larger by 50 nm to 1000 nm than the second vertical distance v2.

As is illustrated in FIG. 1B in combination with FIG. 1D, the first vertical distance v1, along the vertical direction y, is larger than a third vertical distance v3 from a bottom side 1121 of the trench gate structure 112 to the vertical reference level vrL. As is illustrated in FIG. 1D, the second vertical distance v2, along the vertical direction y, is larger than the third vertical distance v3. As is illustrated in FIGS. 1D, a fifth vertical distance v5 extends from the bottom side 1141 of the body region 114 to the vertical reference level vrL along the vertical direction y. A difference d1 of the fifth vertical distance v5 and the first vertical distance v1 is larger than a difference d2 of the first vertical distance v1 and the second vertical distance v2.

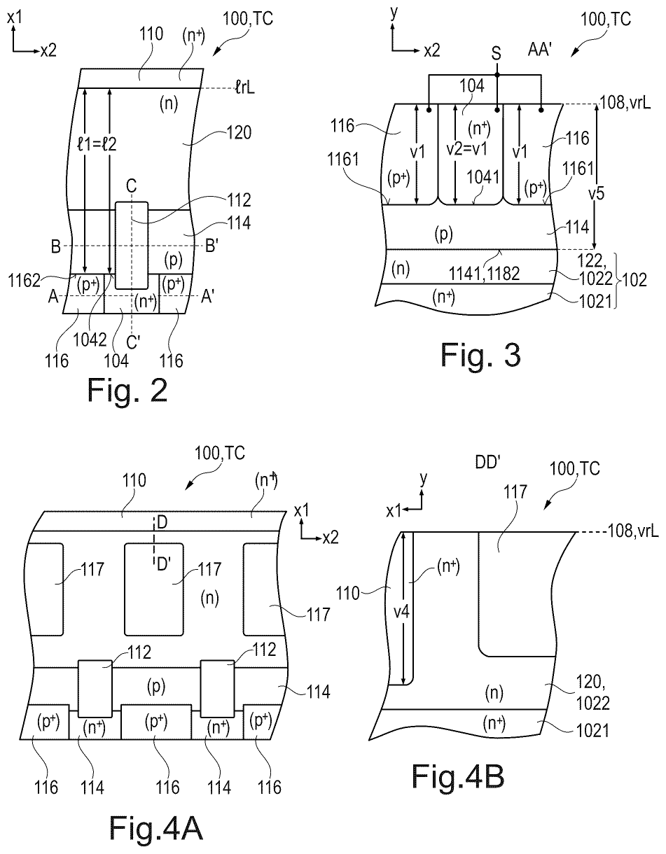

A further configuration example of a FET 100 is illustrated in FIG. 2. The FET 100 may be based on the cross-sectional views of FIGS. 1B, 1C and 1D, and a version of FIG. 1A that is modified in that I1 is equal to I2.

A further configuration example of a FET 100 is illustrated in FIG. 3. The FET 100 may be based on the top and cross-sectional views of FIGS. 1A, 1C and 1D, and a version of FIG. 1B that is modified in that v1 is equal to v2.

The configuration example of a FET 100 illustrated in the top and cross-sectional views of FIGS. 4A and 4B is based on the FET illustrated in FIGS. 1A to 1D and further includes a trench field plate structure 117 arranged, along the first lateral direction x1, between the trench gate structure 112 and the n+-doped drain region 110. For example, n-type dopants of the drain region 110 may line at least part of a sidewall of a drain contact trench extending into the semiconductor substrate 102 from the first surface 108. A fourth vertical distance v4, along the vertical direction y, from a bottom side 1101 of the drain region 110 to the vertical reference level vrL may be larger than the second vertical distance v2 illustrated in any of FIGS. 1B, 1D, 3.

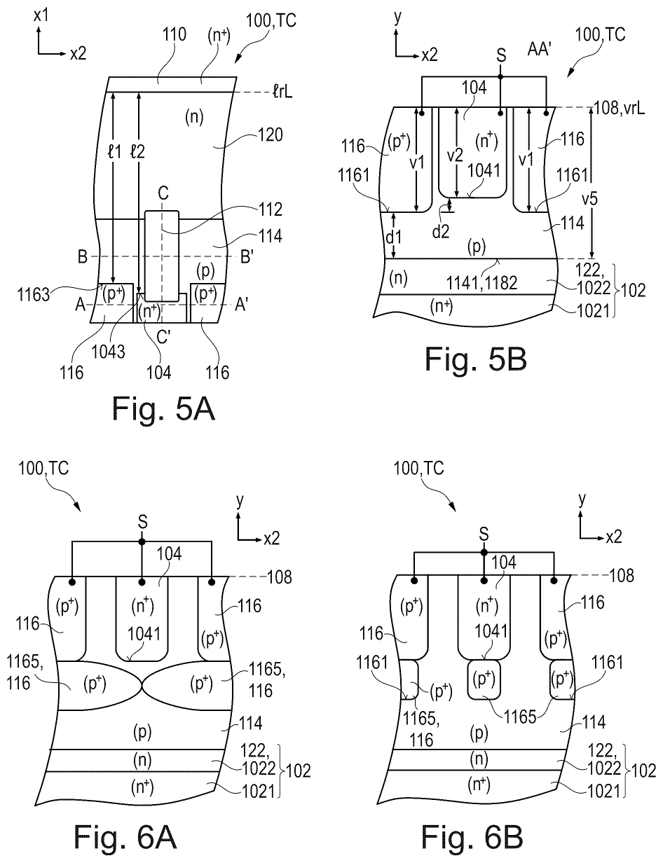

A further configuration example of a FET 100 is illustrated in FIGS. 5A and 5B. The FET 100 is based on the views of the top and cross-sectional views of FIGS. 1A, 1B and further includes a lateral distance, along the second lateral direction x2, between the source region 104 and the body contact region 116. A portion of the body region 114 is arranged between the source region 104 and the body contact region 116.

Further configuration examples of a FET 100 are illustrated in FIGS. 6A and 6B. The FET 100 is based on the views of the cross-sectional view of FIG. 3 and further includes a lateral distance, along the second lateral direction x2, between the source region 104 and the body contact region 116. A portion of the body region 114 is arranged between the source region 104 and the body contact region 116.

Referring to FIG. 6A, each body contact region 116 further includes a p⁺-doped buried body contact sub-region 1165. The p⁺-doped buried body contact sub-regions 1165 of neighboring body contact regions 116 overlap or adjoin one another along the second lateral direction x2. In further examples, the p⁺-doped buried body contact sub-regions 1165 of neighboring body contact regions 116 may have a lateral distance from one another along the second lateral direction x2. Dopants of the p⁺-doped buried body contact sub-region 1165 may be introduced into the semiconductor substrate 102 via a bottom side of the body contact trenches, for example.

Referring to FIG. 6B, a p⁺-doped buried body contact sub-region 1165 is further arranged below the source region 104 and adjoins the bottom side 1041 of the source region 104. Neighboring p⁺-doped buried body contact sub-regions 1165 are spaced from one another along the second lateral direction x2. In further examples, neighboring p⁺-doped buried body contact sub-regions 1165 may overlap or adjoin one another along the second lateral direction x2. Dopants of the p⁺-doped buried body contact sub-region 1165 may be introduced into the semiconductor substrate 102 via a bottom side of the body/source contact trenches, for example.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A field effect transistor (FET) comprising a transistor cell in a semiconductor substrate having a first surface, wherein the transistor cell comprises:
a source region including dopants of a first conductivity type at the first surface of the semiconductor substrate;
a drain region including dopants of the first conductivity type, the drain region being spaced along a first lateral direction from the source region;
a trench gate structure arranged, along the first lateral direction, between the source region and the drain region;
a body region of a second conductivity type that adjoins to the trench gate structure;
a body contact region including dopants of the second conductivity type,
wherein an arrangement of the source region and the body contact region satisfies at least one of the following conditions:
a first vertical distance from a bottom side of the body contact region to a vertical reference level at the first surface is larger than a second vertical distance from a bottom side of the source region to the vertical reference level; and
a first lateral distance, along the first lateral direction, from a first edge of the body contact region to a lateral reference level at the drain region is smaller than a second lateral distance, along the first lateral direction, from a first edge of the source region to the lateral reference level.

2. The FET of claim 1, wherein the first vertical distance is larger by 50 nm to 1000 nm than the second vertical distance.

3. The FET of claim 1, wherein the first lateral distance is smaller by 50 nm to 500 nm than the second lateral distance.

4. The FET of claim 1, wherein the dopants of the second conductivity type of the body contact region line at least part of a sidewall of a body contact trench extending into the semiconductor substrate from the first surface.

5. The FET of claim 1, wherein the first vertical distance is larger than a third vertical distance from a bottom side of the trench gate structure to the vertical reference level.

6. The FET of claim 1, wherein the dopants of the first conductivity type of the source region line at least part of a sidewall of a source contact trench extending into the semiconductor substrate from the first surface.

7. The FET of claim 1, wherein the second vertical distance is larger than a third vertical distance from a bottom side of the trench gate structure to the vertical reference level.

8. The FET of claim 1, wherein the body region adjoins to a bottom side of the trench gate structure.

9. The FET of claim 1, wherein the source region adjoins to the body contact region along a second lateral direction, the second lateral direction being perpendicular to the first lateral direction.

10. The FET of claim 1, wherein the dopants of the first conductivity type of the drain region line at least part of a sidewall of a drain contact trench extending into the semiconductor substrate from the first surface.

11. The FET of claim 10, wherein a fourth vertical distance from a bottom side of the drain region to the vertical reference level is larger than the second vertical distance.

12. The FET of claim 1, further comprising a trench field plate structure arranged, along the first lateral direction, between the trench gate structure and the drain region.

13. The FET of claim 1, wherein a difference of a fifth vertical distance and the first vertical distance is larger than a difference of the first vertical distance and the second vertical distance, the fifth vertical distance being from a bottom side of the body region to the vertical reference level.

14. The FET of claim 1, wherein the semiconductor substrate comprises a base substrate of the first conductivity type and a semiconductor layer of the first conductivity type, wherein the semiconductor layer is arranged on the base substrate and has a smaller concentration of dopants of the first conductivity type than the base substrate.

15. The FET of claim 14, wherein the body region is a well region in the semiconductor layer, wherein a pn junction between the body region and the semiconductor layer includes a side area and a bottom area, and wherein a drift region as part of the semiconductor layer is arranged between the side area and the drain region, and a sub-region of the semiconductor layer is arranged between the bottom area and the base substrate.

16. The FET of claim 15, wherein the body region, the body contact region and the semiconductor substrate are configured to provide an electric breakdown location of the pn junction at or close to the bottom area.

17. The FET of claim 16, wherein the electric breakdown location of the pn junction at the bottom area is directly below a bottom side of the body contact region.

18. The FET of claim 1, wherein the body contact region includes a p⁺-doped buried body contact sub-region, and wherein the p⁺-doped buried body contact sub-region overlaps or adjoins a further p⁺-doped buried body contact sub-region of a further body contact region of the FET.

19. A method of manufacturing a field effect transistor (FET) comprising forming a transistor cell in a semiconductor substrate having a first surface, wherein forming the transistor cell comprises:
forming a source region including dopants of a first conductivity type at the first surface of the semiconductor substrate;
forming a drain region including dopants of the first conductivity type, the drain region being spaced along a first lateral direction from the source region;
forming a trench gate structure arranged, along the first lateral direction, between the source region and the drain region;
forming a body region of a second conductivity type that adjoins to the trench gate structure;
forming a body contact region including dopants of the second conductivity type,
wherein an arrangement of the source region and the body contact region satisfies at least one of the following conditions:
a first vertical distance from a bottom side of the body contact region to a vertical reference level at the first surface is larger than a second vertical distance from a bottom side of the source region to the vertical reference level; and
a first lateral distance, along the first lateral direction, from a first edge of the body contact region to a lateral reference level at the drain region is smaller than a second lateral distance, along the first lateral direction, from a first edge of the source region to the lateral reference level.

20. The method of claim 19, wherein forming the source region comprises:
forming a source contact trench extending into the semiconductor substrate from the first surface;
introducing the dopants of the first conductivity type of the source region through a sidewall of the source contact trench into the semiconductor substrate; and
filling the source contact trench with a conductive material.

21. The method of claim 19, wherein forming the body contact region comprises:
forming a body contact trench extending into the semiconductor substrate from the first surface;
introducing the dopants of the second conductivity type of the body contact region through a sidewall of the body contact trench into the semiconductor substrate; and
filling the body contact trench with a conductive material.
